(19) United States
(12) Patent Application Publication
(10) Pub. No.: US 2011/0280334 A1
(43) Pub. Date: Nov. 17, 2011

(54) DIGITAL AMPLITUDE MODULATOR AND POLAR TRANSMITTER USING THEREOF

(75) Inventors: Joon Hyung Lim, Gyeonggi-do (KR); Han Jin Cho, Seoul (KR); Yong Il Kwon, Gyeonggi-do (KR); Kyung Hee Hong, Seoul (KR); Koon Shik Cho, Seoul (KR); Myeung Su Kim, Gyeonggi-do (KR)

(73) Assignee: SAMSUNG ELECTRO-MECHANICS CO., LTD., Gyunggi-do (KR)

(21) Appl. No.: 12/859,800

(22) Filed: Aug. 20, 2010

(30) Foreign Application Priority Data
May 17, 2010 (KR) 10-2010-0045943

(51) Int. Cl. H04L 27/00; H03C 1/02

(52) U.S. Cl. 375/295; 332/149

(57) ABSTRACT

The present invention provides a digital amplitude modulator and polar transmitter using the same. The polar transmitter includes: a polar converter for converting an input signal into an amplitude information signal and a phase information signal, and outputting the converted amplitude and phase information signal; a sigma-delta modulator for receiving a fractional part of the amplitude information signal, and generating a correcting value for an integer part of the amplitude information signal; a phase-modulator for upward-modulating the phase information signal outputted from the polar converter, and outputting carrier waves including the upward-modulated phase information signal; and a digital power amplifier for generating an output signal whose amplitude corresponds to the integer part of the amplitude information signal which is subjected to correction by the correcting value, and outputting combining the output signal with an output value of the phase-modulator to output the combined signal.

### CROSS-REFERENCE TO RELATED APPLICATIONS

This application claims the benefit of Korean Patent Application No. 10-2010-0045943 filed with the Korea Intellectual Property Office on May 17, 2010, the disclosure of which is incorporated herein by reference.

### BACKGROUND OF THE INVENTION

1. Field of the Invention

The present invention relates to a wireless data communication system; and, more particularly, to a technology for transmitting wireless data by converting a baseband signal into a signal in the polar form.

2. Description of the Related Art

A polar transmitter divides a transmission signal into amplitude information and phase information, phase-modulates the phase information through a Voltage Controlled Oscillator (VCO) and a Phase Locked Loop (PLL), and mixes the phase-modulated information with the amplitude information amplified by a power amplifier, thereby transmitting the mixed information. Since such a polar transmitter amplifies the amplitude and phase information in paths different from each other, the polar transmitter has high power efficiency over the conventional RF transmitter.

However, in case of the conventional polar transmitter, an RF power amplifier with high-linearity is required for amplitude-modulation. The RF power amplifier and I/Q modulator have a high power consumption. Additionally, the conventional polar transmitter has a construction in which a baseband circuit is implemented using an analog scheme, which results in limitation of bandwidth expansion and downsizing thereof.

### SUMMARY OF THE INVENTION

The present invention has been proposed in order to overcome the above-described problems and it is, therefore, an object of the present invention to provide a polar transmitter, which has a construction in which an RF power amplifier is digitized, thereby reducing the power consumption and size thereof, as well as improving linearity of the RF power amplifier through a separate feedback means.

In accordance with one aspect of the present invention to achieve the object, there is provided a polar transmitter including: a polar converter for converting an input signal into an amplitude information signal and a phase information signal, and outputting the converted amplitude and phase information signal; a sigma-delta modulator for receiving a fractional part of the amplitude information signal, and generating a correcting value for an integer part of the amplitude information signal; a phase-modulator for upward-modulating the phase information signal outputted from the polar converter, and outputting carrier waves including the upward-modulated phase information signal; and a digital power amplifier for generating an output signal whose amplitude corresponds to the integer part of the amplitude information signal which is subjected to correction by the correcting value, and outputting combining the output signal with an output value of the phase-modulator to output the combined signal.

The digital power amplifier includes a plurality of power amplification units, and the output signal is obtained by summing outputs of the power amplification units.

The digital power amplifier either turns on or turns off each of the power amplification units according to the integer part of the amplitude information signal which is subjected to correction by the correcting value.

The digital power amplifier has a construction in which the number of power amplification units to be turned on is increased in proportion to the integer part of the amplitude information signal which is subjected to correction by the correcting value.

The polar transmitter further includes a feedback controller for controlling amplitude of the output signal in such a manner that output signals of the digital power amplifier are lineally increased in proportion to the amplitude information signal.

The feedback controller controls amplitude of the output signal by adjusting the level of voltage which is supplied to the digital power amplifier.

The feedback controller controls amplitude of the output signal by adjusting the level of a bias voltage of a transistor included in each of the power amplification units in the digital power amplifier.

In accordance with another aspect of the present invention to achieve the object, there is provided a digital amplitude modulator including: an input unit for receiving amplitude information signal including an integer part and a fractional part; a sigma-delta modulator for receiving the fractional part of the amplitude information signal, and generating a correcting value for the integer part of the amplitude information signal; and a digital power amplifier for generating an output signal whose amplitude corresponds to the integer part of the amplitude information signal which is subjected to correction by the correcting value.

The digital power amplifier includes a plurality of power amplification units, and the output signal is obtained by summing outputs of the power amplification units.

The digital power amplifier either turns on or turns off each of the power amplification units according to the integer part of the amplitude information signal which is subjected to correction by the correcting value.

The digital power amplifier has a construction in which the power amplification units to be turned on are increased in proportion to the integer part of the amplitude information signal which is subjected to correction by the correcting value.

The digital amplitude modulator further includes a feedback controller for controlling amplitude of the output signal in such a manner that output signals of the digital power amplifier are lineally increased in proportion to the amplitude information signal.

The feedback controller controls amplitude of the output signal by adjusting the level of voltage which is supplied to the digital power amplifier.

The feedback controller controls amplitude of the output signal by adjusting the level of a bias voltage of a transistor included in each of the power amplification units in the digital power amplifier.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram showing a polar transmitter 100 in accordance with one embodiment of the present invention;

FIG. 2 is a block diagram showing a detailed construction of the digital power amplifier 108 in accordance with one embodiment of the present invention;

FIG. 3 is a graph for explaining a correction effect of output values of the digital power amplifier 108 by a sigma-delta modulator 104; and

FIGS. 4A and 4B are circuit diagrams showing a sigma-delta modulator 104 in accordance with one embodiment of the present invention, respectively;

FIG. 5 is a circuit diagram showing a sigma-delta modulator 104 in accordance with another embodiment of the present invention; and

FIG. 6 is a graph showing an error between input and output of the digital power amplifier 108 in accordance with one embodiment of the present invention.

### DETAILED DESCRIPTION OF THE PREFERABLE EMBODIMENTS

Hereinafter, a preferred embodiment according to the present invention will be described with to the accompanying drawings. However, this is only for illustrative example, and the present invention is not limited thereto.

In the following description of the present invention, a detailed description of known functions and configuration incorporated herein will be omitted when it may make the subject matter of the present invention rather unclear.

Terms which will be later are defined on the basis of the entire contents of the present specification. Technical idea of the present invention is decided by the scope of claims, and the following embodiment is only for illustrative means to help those skilled in the art to understand.

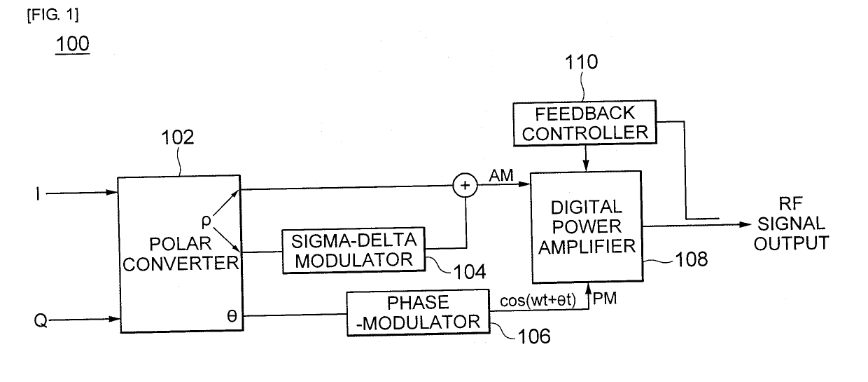

FIG. 1 is a block diagram showing a polar transmitter 100 in accordance with one embodiment of the present invention.

As shown in FIG. 1, the polar transmitter 100 includes a polar converter 102, a sigma-delta modulator 104, a phase-modulator 106, a digital power amplifier 108, and a feedback controller 110.

The polar converter 102 converts an input signal into a signal in the polar form. The input signal, for example, may be a signal obtained by performing I/Q modulation of a baseband signal, or a signal obtained by directly converting a baseband signal into a signal in the polar form.

The polar signal includes an amplitude information signal and a phase information signal of the input signal, and the polar signal is outputted in the digital form. The amplitude information signal includes an integer part and a fractional part, and for example, the amplitude information signal may be constituted by the integer part of N bits and the fractional part of M bits. The polar converter 102 outputs the integer part (N bits) and the fractional part (M bits) of the amplitude information signal in such a manner to be divided from each other, and the fractional part is combined with the integer part after being subjected to the sigma-delta modulator 104.

The sigma-delta modulator 104 receives from the polar converter 102 the fractional part of the amplitude information signal, and generates a correcting value for the integer part of the amplitude information signal. The generated correcting value is combined with the integer part of the amplitude information signal and the resultant value is inputted to the digital power amplifier 108 to be described later. A detailed description will be given of a construction of the sigma-delta modulator 104.

The phase-modulator 106 upward-modulates the phase information signal outputted from the polar converter 102, and carries the upward-modulated information signal on carrier waves.

The digital power amplifier 108 generates an output signal which has amplitude corresponding to a value obtained by summing the integer part of the amplitude signal information and the correcting value outputted from the sigma-delta modulator 104, and combines the output signal with an output value of the phase-modulator 106 to output the combined signal.

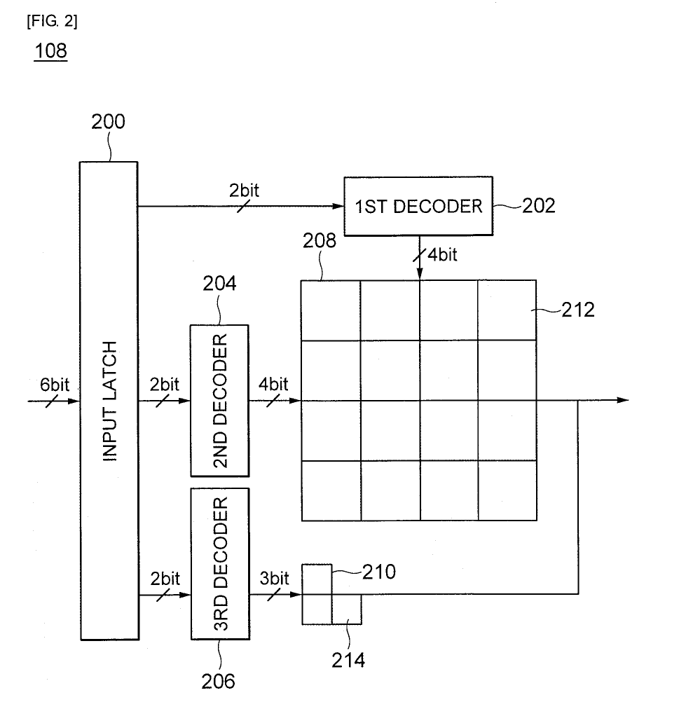

FIG. 2 is a block diagram showing a detailed construction of the digital power amplifier 108 in accordance with one embodiment of the present invention.

As shown in FIG. 2, the digital power amplifier 108 includes an input latch 200, a first decoder 202, a second decoder 204, a third decoder 206, a first power amplification matrix 208, and a second power amplification matrix 210.

The digital power amplifier 108 shown in FIG. 2 is a 6-bit digital RF power amplifier. The 6-bit digital RF power amplifier receives an offset binary input of 6 bits and outputs an output signal whose amplitude corresponds to the received offset binary input. However, this is only for illustrative example, and the number of input bits of the digital power amplifier 108 may be set depending on the number of bits (N bits) of the integer part in the amplitude information signal outputted from the polar converter 102.

The input latch 200 receives the integer part (N bits) of the amplitude information signal, and distributes the received integer part to first to third decoders 202 to 206, respectively. In this case, low-order bits (2 bits) of the N bits are inputted to the third decoder 206, half remaining bits are distributed to the first decoder 202, and the others are distributed to the second decoder 204. In an embodiment shown in FIG. 2, first and second bits in 6 bits are inputted to the first decoder 202, third and fourth bits in 6 bits are inputted to the second decoder 204, and fifth and sixth bits in 6 bits are inputted to the third decoder 206.

The first and second decoders 202 and 204 generate a column control signal and a low control signal of a first power amplification matrix 208 according to the value of bits inputted from the input latch 200. The third decoder 206 generates a control signal of the second power amplification matrix 210 according to the value of bits inputted from the input latch.

The first and second power amplification matrixes 208 and 210 include a number of power amplification units, respectively. The first and second power amplification matrixes 208 and 210 receive the column control signal, the low control signal, or the control signal outputted from the third decoder 206, and turn on/off each of the power amplification units based on the received control signals to thereby generate output values. In this case, each of the power amplification units 212 in the first power amplification matrix 208 outputs a signal whose amplitude is four times as large as that of the power amplification unit 214 in the second power amplification matrix 210. That is, power outputted by one power amplification unit 212 in the first power amplification matrix 208 is the same as that of four power amplification units 214 in the second power amplification matrix 210. In the embodiment shown in FIG. 2, the first power amplification matrix 208 includes 16 power amplification units 212, and the second power amplification matrix 210 includes 3 power amplification units. The output signal of the digital power amplifier 108 has a value obtained by summing outputs for each of the power amplification units in first and second power amplification matrix 208 and 210.

In the digital power amplifier 108 with the above-described construction, the first to third decoders 202 to 206 generate control signals for each of the power amplification units 212 and 214 according to the integer part of the inputted amplitude information signal. Then, the first to third decoders 202 to 206 adjust the amplitude of the output signal by turning on/off each of the power amplification units 212 and 214 according to each of the generated control signals. That is, the integer part of the amplitude information signal operates similarly to a thermometer code. The digital power amplifier 108 has a construction in which the number of the power amplification units 212 and 214 to be turned on is increased in proportion to the integer part of the amplitude information signal.

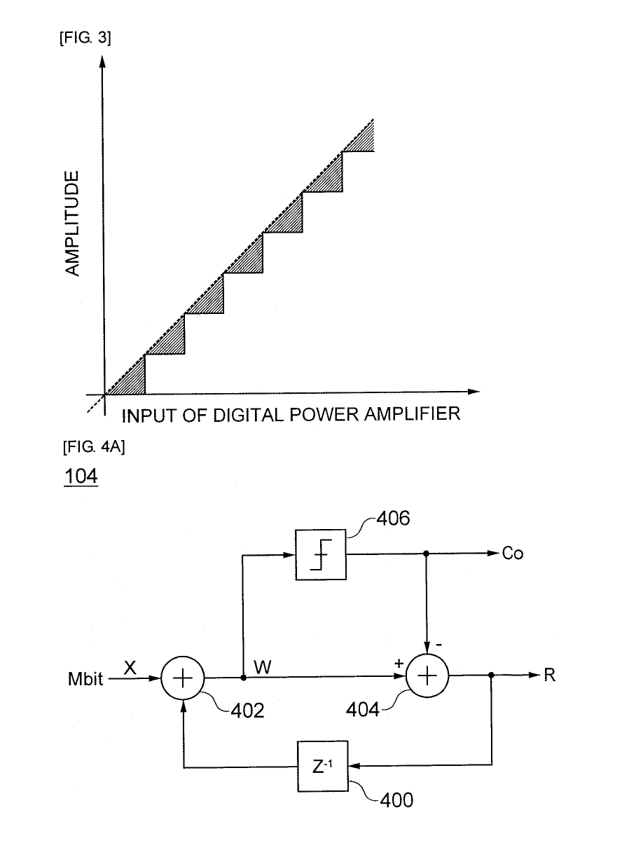

Meanwhile, when the digital power amplifier 108 is constructed as described in FIG. 2, the output value of the digital power amplifier 108 varies in the stepped shape based on power outputted from one power amplification unit 212 in the second power amplification matrix 210 as a basic unit. That is, in case of the digital power amplifier 108 shown in FIG. 2, the output value varies to be shaped like 64 steps according to the input value. However, since an input value of the digital power amplifier 108 continues to be varied, when the digital power amplifier 108 is constructed as described above, the output value becomes discontinuous as shown in FIG. 3. In FIG. 3, dotted lines indicate amplitude variation of ideal output values, solid lines indicate output values of the digital power amplifier 108 which is constructed with only an integer part of the amplitude information signal, and areas filled by oblique lines indicate a difference between the ideal output value and the output value of the integer part, respectively.

In order to solve the above-described problem and to ensure linearity of the digital power amplifier 108, in the embodiment of the present invention, a correcting value for the integer part of the amplitude information signal is generated by using a fractional part of the amplitude information signal outputted from the polar converter 102. That is, in the embodiment of the present invention, the sigma-delta modulator 104 is used for correction of the integer part of the amplitude information signal which is inputted to the digital power amplifier 108. The output value of the sigma-delta modulator 104 is summed with the integer part of the amplitude information signal, and then the resultant value is inputted to the digital power amplifier 108.

FIGS. 4A and 4B are circuit diagrams showing a sigma-delta modulator 104 in accordance with one embodiment of the present invention, respectively. FIG. 4A is a circuit diagram showing a sigma-delta modulator 104, and FIG. 4B shows a circuit equivalent to the sigma-delta modulator 104 shown in FIG. 4A.

As shown in FIGS. 4A and 4B, the sigma-delta modulator 104 includes a delay device 400, summers 402 and 404, and a comparator 406. FIGS. 4A and 4B show the sigma-delta modulator 104 constructed with 1^{st} order sigma-delta modulator. However, the oversampling ratio and order of the sigma-delta modulator 104 may be properly set according to performance of the digital power amplifier 108 and output spectrum mask of the polar transmitter 100. A signal transfer function and a noise transfer function of 1^{st} sigma-delta modulator 104 are defined by equation (1) below.

Co=X(z)+E(z)(1−Z⁻¹) (1)

In equation (1), X(z) denotes a signal transfer function, and E(z)(1−Z⁻¹) denotes a noise transfer function.

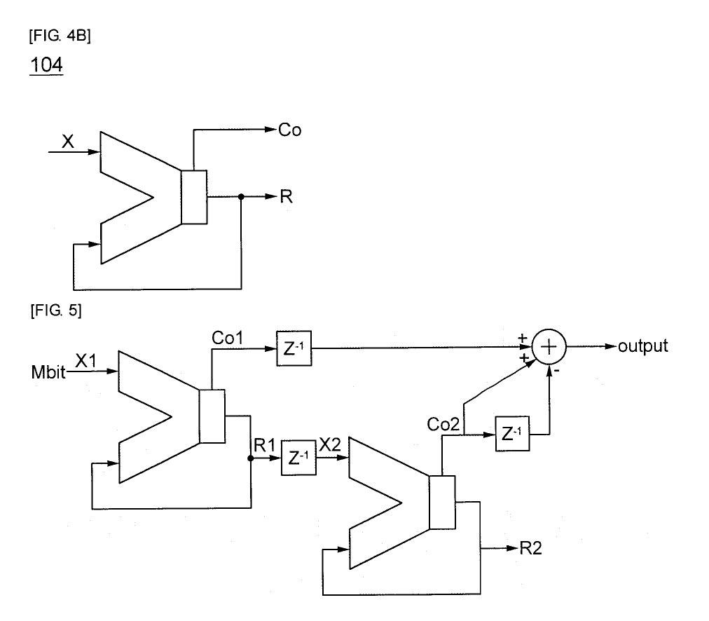

FIG. 5 shows a sigma-delta modulator 104 in accordance with another embodiment of the present invention. The sigma-delta modulator 104 shown in FIG. 5 is a 2^{nd} sigma-delta modulator constructed through connection of two 1^{st} sigma-delta modulators 104.

In the sigma-delta modulator 104 shown in FIG. 5, a signal transfer function and a noise transfer function are calculated as defined by equation (2) below.

Co₂−Co₂Z⁻¹+Co₁Z⁻¹=X₂(z)Z⁻¹+E₂(z)(1−Z⁻¹)² (2)

In equation (2), Co₂−Co₂Z⁻¹+Co₁Z⁻¹ denotes an output of 2^{nd} sigma-delta modulator 104, X₂(z)Z⁻¹ denotes a signal transfer function, and E₂(z)(1−Z⁻¹)² denotes a noise transfer noise function.

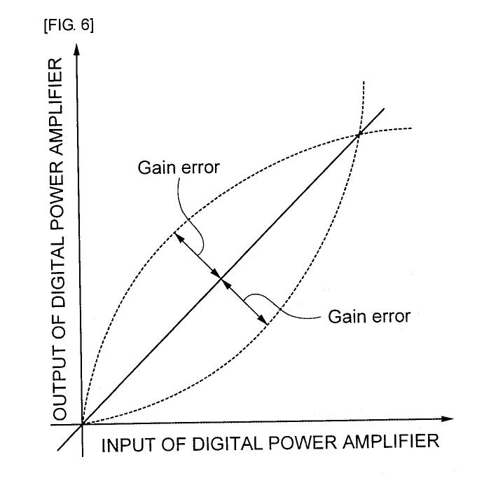

Meanwhile, in case of the polar transmitter 100 with the above-described construction, the output value of the digital power amplifier 108 should be linearly increased according to increase in an input value of the digital power amplifier 108, as indicated by dotted lines in a graph of FIG. 6. However, when the polar transmitter 100 actually operates, non-linearity of power amplification units constituting the digital power amplifier 108 causes nonlinear-increase in the output value of the digital power amplifier 108, as indicated by the dotted line in FIG. 6. For removal of such non-linearity, the polar transmitter 100 of the present invention may further include a feedback controller 110.

The feedback controller 110 senses the output value of the digital power amplifier 108, and compares the sensed output value with a reference value to thereby determine whether or not the digital power amplifier 108 linearly operates. The reference value, for example, may be an input value of the digital power amplifier 108. According to the result of comparison, when the feedback controller 110 determines that the digital power amplifier 108 nonlinearly operates, the polar transmitter 100 transmits a feedback signal to the digital power amplifier 108, and controls the digital power amplifier 108 so that output of the digital power amplifier 108 can be maintained to be linear.

The feedback controller 110 can control the output of the digital power amplifier 108 by using a means to be described as an example. First, the feedback controller 110 can control the amplitude of an output signal by adjusting the level of a power supply voltage (Vdd) supplied to the digital power amplifier 108. In this case, the feedback signal may be a signal used to adjust the level of the power supply voltage (Vdd). Since the amplitude of a signal outputted from each of the power amplification units varies depending on the level of the power supply voltage supplied to the digital power amplifier 108, the amplitude of the summed output signal varies as well.

Also, the feedback controller 110 can control output of the digital power amplifier 108 by adjusting the level of a bias voltage supplied to the digital power amplifier 108. In this case, the feedback signal may be a signal used for adjusting the level of the bias voltage. As in the example described above, since the amplitude of the signal outputted from each of the power amplification units varies depending on the level of the bias voltage supplied to the digital power amplifier 108, the amplitude of summed output signal varies as well.

In the polar transmitter of the present invention, a digital RF DAC (Digital to Analog converter) scheme is applied to an RF power amplifier, so that it is possible to minimize the size of the polar transmitter, as well as to reduce power consumption of the polar transmitter.

Also, a separate feedback manes is used to correct output of the RF power amplifier, so that it is possible to implement linear operation of the polar transmitter.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A polar transmitter comprising:
a polar converter for converting an input signal into an amplitude information signal and a phase information signal, and outputting the converted amplitude and phase information signal;
a sigma-delta modulator for receiving a fractional part of the amplitude information signal, and generating a correcting value for an integer part of the amplitude information signal;
a phase-modulator for upward-modulating the phase information signal outputted from the polar converter, and outputting carrier waves including the upward-modulated phase information signal; and
a digital power amplifier for generating an output signal whose amplitude corresponds to the integer part of the amplitude information signal which is subjected to correction by the correcting value, and outputting combining the output signal with an output value of the phase-modulator to output the combined signal.

2. The polar transmitter of claim 1, wherein the digital power amplifier includes a plurality of power amplification units, and the output signal is obtained by summing outputs of the power amplification units.

3. The polar transmitter of claim 2, wherein the digital power amplifier either turns on or turns off each of the power amplification units according to the integer part of the amplitude information signal which is subjected to correction by the correcting value.

4. The polar transmitter of claim 3, wherein the digital power amplifier has a construction in which the number of power amplification units to be turned on is increased in proportion to the integer part of the amplitude information signal which is subjected to correction by the correcting value.

5. The polar transmitter of claim 2, further comprising a feedback controller for controlling amplitude of the output signal in such a manner that output signals of the digital power amplifier are lineally increased in proportion to the amplitude information signal.

6. The polar transmitter of claim 5, wherein the feedback controller controls amplitude of the output signal by adjusting the level of voltage which is supplied to the digital power amplifier.

7. The polar transmitter of claim 5, wherein the feedback controller controls amplitude of the output signal by adjusting the level of a bias voltage of a transistor included in each of the power amplification units in the digital power amplifier.

8. A digital amplitude modulator comprising:
an input unit for receiving amplitude information signal including an integer part and a fractional part;
a sigma-delta modulator for receiving the fractional part of the amplitude information signal, and generating a correcting value for the integer part of the amplitude information signal; and
a digital power amplifier for generating an output signal whose amplitude corresponds to the integer part of the amplitude information signal which is subjected to correction by the correcting value.

9. The digital amplitude modulator of claim 8, wherein the digital power amplifier includes a plurality of power amplification units, and the output signal is obtained by summing outputs of the power amplification units.

10. The digital amplitude modulator of claim 9, wherein the digital power amplifier either turns on or turns off each of the power amplification units according to the integer part of the amplitude information signal which is subjected to correction by the correcting value.

11. The digital amplitude modulator of claim 10, wherein the digital power amplifier has a construction in which the power amplification units to be turned on are increased in proportion to the integer part of the amplitude information signal which is subjected to correction by the correcting value.

12. The digital amplitude modulator of claim 9, further comprising a feedback controller for controlling amplitude of the output signal in such a manner that output signals of the digital power amplifier are lineally increased in proportion to the amplitude information signal.

13. The digital amplitude modulator of claim 12, wherein the feedback controller controls amplitude of the output signal by adjusting the level of voltage which is supplied to the digital power amplifier.

14. The digital amplitude modulator of claim 12, wherein the feedback controller controls amplitude of the output signal by adjusting the level of a bias voltage of a transistor included in each of the power amplification units in the digital power amplifier.
